(19) United States
(12) Patent Application Publication
(10) Pub. No.: US 2025/0053090 A1
(43) Pub. Date: Feb. 13, 2025

(54) RESIST UNDERLAYER COMPOSITION AND METHOD OF FORMING PATTERNS USING THE COMPOSITION

(71) Applicant: SAMSUNG SDI CO., LTD., Yongin-si (KR)

(72) Inventors: Hwayoung JIN, Suwon-si (KR); Yoojeong CHOI, Suwon-si (KR); Jaeyeol BAEK, Suwon-si (KR); Soonhyung KWON, Suwon-si (KR); Seongjin KIM, Suwon-si (KR); Ahra CHO, Suwon-si (KR)

(21) Appl. No.: 18/767,428

(22) Filed: Jul. 9, 2024

(30) Foreign Application Priority Data
Aug. 10, 2023 (KR) 10-2023-0105175

(51) Int. Cl. G03F 7/039; G03F 7/004; G03F 7/038

(52) U.S. Cl. CPC G03F 7/0397; G03F 7/0042; G03F 7/0045; G03F 7/0382; G03F 7/0387; G03F 7/0388; G03F 7/0395

(57) ABSTRACT

Disclosed are a resist underlayer composition, and a method of forming a pattern using the resist underlayer composition. The resist underlayer composition includes a polymer including a structural unit represented by Chemical Formula 1, a structural unit represented by Chemical Formula 2, or a combination thereof, a compound represented by Chemical Formula 3, and a solvent. The definitions of Chemical Formula 1 to Chemical Formula 3 are as described in the specification.

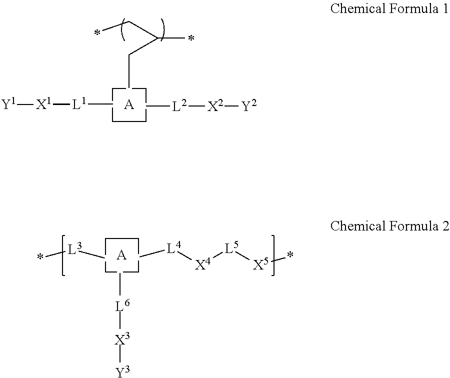

(R¹)ₓ(R²)_{y}(R³)Sn—(R⁴)_{(3-x-y)} Chemical Formula 3

### CROSS-REFERENCE TO RELATED APPLICATION

The present application claims priority to and the benefit of Korean Patent Application No. 10-2023-0105175, filed on Aug. 10, 2023, in the Korean Intellectual Property Office, the entire content of which is hereby incorporated by reference.

### BACKGROUND

### 1. Field

Embodiments of this disclosure relate to a resist underlayer composition, and a method of forming patterns using the same.

### 2. Description of the Related Art

Recently, a semiconductor industry has developed an ultra-fine technique having a pattern of several to several tens of nanometers in size. Such ultrafine techniques benefit from effective lithographic techniques.

The lithographic technique is a processing method that involves coating a photoresist film on a semiconductor substrate such as, for example, a silicon wafer to form a thin film, irradiating activating radiation such as, for example, ultraviolet rays through a mask pattern on which the device pattern is drawn, developing it to obtain a photoresist pattern, and etching the substrate using the obtained photoresist pattern as a protective film to form a fine pattern corresponding to the pattern on the surface of the substrate.

As semiconductor patterns become increasingly finer, a thickness of the photoresist layer should be thin, and accordingly, a thickness of the resist underlayer should also be thin. The resist underlayer should keep the photoresist pattern despite the thinness, for example, to have a substantially uniform thickness as well as excellent or suitable close contacting property and adherence to the photoresist. the resist underlayer should have a high refractive index and low extinction coefficient for the light used in photolithography and a faster etch rate than the photoresist layer.

### SUMMARY

The resist underlayer composition according to some embodiments of the present disclosure provides a resist underlayer that does not cause resist pattern collapse even in a fine patterning process and has improved sensitivity to an exposure light source, thereby improving patterning performance and energy efficiency.

A resist underlayer composition according to some embodiments provides a resist underlayer having improved adhesion between a resist and a resist underlayer.

Some embodiments provide a method of forming a pattern using the resist underlayer composition.

A resist underlayer composition according to some embodiments includes a polymer including a structural unit represented by Chemical Formula 1, a structural unit represented by Chemical Formula 2, or a combination thereof, a compound represented by Chemical Formula 3, and a solvent:

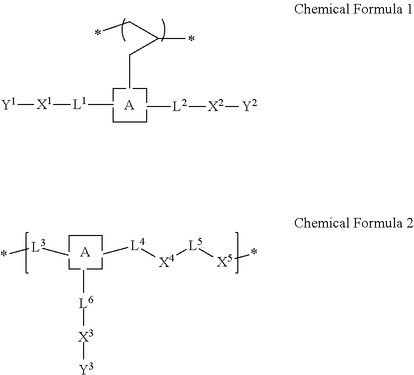

wherein, in Chemical Formula 1 and Chemical Formula 2,
A is a heterocyclic group including a nitrogen atom in a ring,
L¹ to L⁶ are each independently a single bond (e.g., a single covalent bond), a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C1 to C20 heteroarylene group, or a combination thereof,
X¹ to X⁵ are each independently a single bond (e.g., a single covalent bond), —O—, —S—, —S(═O)—, —S(═O)₂—, —C(═O)—, —(CO)O—, —O(CO)O—, —NR^{a}— (wherein R^{a} is hydrogen, deuterium, or a C1 to C10 alkyl group), or a combination thereof,
Y¹ to Y³ are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C3 to C20 heteroaryl group, or a combination thereof, and
* is a linking point:

(R¹)ₓ(R²)_{y}(R³)Sn—(R⁴)_{(3-x-y)} Chemical Formula 3
wherein, in Chemical Formula 3,
R¹, R², and R⁴ are each independently hydrogen, deuterium, a cyano group, an oxo group (═O), an azido group (—N₃), a halogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 heteroalkyl group, a substituted or unsubstituted C2 to C20 heteroalkenyl group, a substituted or unsubstituted C2 to C20 heteroalkynyl group, a substituted or unsubstituted C3 to C20 cycloalkyl group, a substituted or unsubstituted C2 to C20 heterocycloalkyl group, a substituted or unsubstituted C6 to C30 aryl group, a substituted or unsubstituted C3 to C30 heteroaryl group, —OR^{b}, —C(═O)R^{c}, —C(═O)OR^{d}, —OC(═O)OR^{e}, —NR^{f}R^{g}, —NR^{h}(C═O)Rⁱ (wherein, R^{b} to Rⁱ are each independently hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, or a substituted or unsubstituted C6 to C30 aryl group), or a combination thereof,
R³ is —OR^{j}, —C(═O)R^{k}, —C(═O)OR^{l}, or —OC(═O)OR^{m}, or -L^{a}-O—Rⁿ (wherein L^{a} is a substituted or unsubstituted C1 to C5 alkylene group, or a substituted or unsubstituted C6 to C16 arylene group, and R^{j} to Rⁿ are each independently hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, or a substituted or unsubstituted C6 to C20 aryl group),
x and y are each independently selected from integers from 0 to 2, and 0≤x+y≤².

In some embodiments, A may be represented by one or more selected from Chemical Formula A-1 to Chemical Formula A-4.

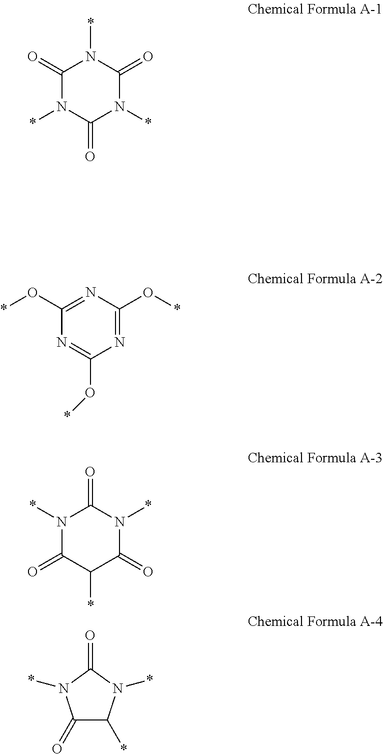

In Chemical Formula A-1 to Chemical Formula A-4, * represents a portion bonded to another atom or group.

In some embodiments, L¹ to L⁶ are each independently a single bond (e.g., a single covalent bond), a substituted or unsubstituted C1 to C10 alkylene group, a substituted or unsubstituted C1 to C10 heteroalkylene group, or a combination thereof, X¹ to X⁵ are each independently a single bond (e.g., a single covalent bond), —O—, —S—, —C(═O)—, —(CO)O—, —O(CO)O—, or a combination thereof, and Y¹ to Y³ are each independently a substituted or unsubstituted C1 to C10 alkyl group, a substituted or unsubstituted C2 to C10 alkenyl group, a substituted or unsubstituted C1 to C10 heteroalkyl group, a substituted or unsubstituted C2 to C10 heteroalkenyl group, a substituted or unsubstituted C3 to C20 cycloalkyl group, a substituted or unsubstituted C2 to C20 heterocycloalkyl group, a substituted or unsubstituted C6 to C20 aryl group, or a combination thereof.

At least one selected from R¹, R², and R⁴ may be a cyano group, an oxo group (═O), an azido group (—N₃), —OR^{b}, —C(═O)R^{c}, —C(═O)OR^{d}, —OC(═O)OR^{e}, —NR^{f}R^{g}, or —NR^{h}(C═O)Rⁱ (wherein R^{b} to Rⁱ may each independently be hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, or a substituted or unsubstituted C6 to C30 aryl group).

R¹, R², and R⁴ may be an oxo group (═O), an azido group (—N₃), a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C30 aryl group, —OR^{b}, NR^{f}R^{g}, —NR^{h}(C═O)Rⁱ (wherein R^{b}, and R^{f} to Rⁱ may each independently be hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, or a substituted or unsubstituted C6 to C30 aryl group), or a combination thereof, and R³ may be —OR^{j} (wherein R^{j} may be hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, a substituted or unsubstituted C6 to C20 aryl group, or a combination thereof).

R¹, R², and R⁴ may each independently be hydrogen, deuterium, an oxo group (═O), a substituted or unsubstituted C1 to C20 alkyl group, a substituted or unsubstituted C1 to C20 heteroalkyl group, a substituted or unsubstituted C6 to C30 aryl group, —OR^{b}, —C(═O)R^{c}, —C(═O)OR^{d}, —OC(═O)OR^{e} (wherein R^{b} to R^{e} may each independently be hydrogen, deuterium, a substituted or unsubstituted C1 to C10 alkyl group, or a substituted or unsubstituted C6 to C30 aryl group), or a combination thereof, and R³ may be —OR^{j}, or —C(═O)OR^{l} (wherein R^{j} and R^{l} may each independently be hydrogen, deuterium, a substituted or unsubstituted C1 to C10 alkyl group, a substituted or unsubstituted C1 to C10 heteroalkyl group, a substituted or unsubstituted C6 to C20 aryl group, or a combination thereof).

The structural unit represented by Chemical Formula 1 may be represented by Chemical Formula 1-1 or Chemical Formula 1-2, and the structural unit represented by Chemical Formula 2 may be represented by any one selected from Chemical Formula 2-1 to Chemical Formula 2-3:

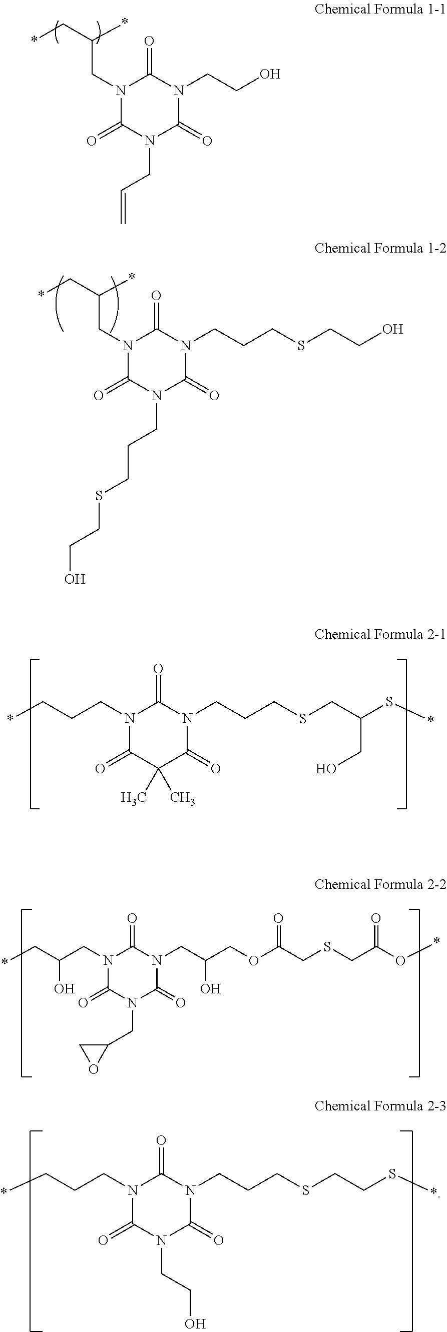

The compound represented by Chemical Formula 3 may be represented by any one or more selected from Chemical Formula 3-1 to Chemical Formula 3-4:

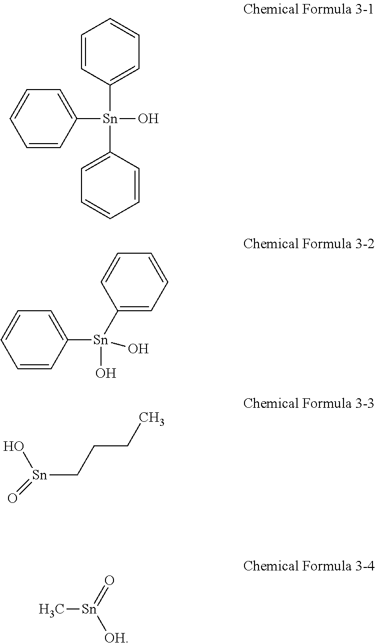

A weight average molecular weight of the polymer may be about 1,000 g/mol to about 300,000 g/mol.

The compound may be included in an amount of about 10 to about 800 parts by weight based on 100 parts by weight of the polymer.

The compound may be included in an amount of about 30 parts by weight to about 500 parts by weight based on 100 parts by weight of the polymer.

The polymer may be included in an amount of about 0.1 wt % to about 50 wt % based on a total weight of the resist underlayer composition.

The compound may be included in an amount of about 0.01 wt % to about 30 wt % based on a total weight of the resist underlayer composition.

The resist underlayer composition may further include one or more polymers selected from an acrylic resin, an epoxy resin, a novolac-based resin, a glycoluril-based resin, and a melamine-based resin.

The resist underlayer composition may further include additives such as a surfactant, a thermal acid generator, a photo acid generator, a plasticizer, or a combination thereof.

According to some embodiments, a method of forming a pattern includes forming a film to be etched on a substrate, coating the resist underlayer composition according to some embodiments on the film to be etched to form a resist underlayer, forming a photoresist pattern on the resist underlayer, and etching the resist underlayer and the film to be etched sequentially using the photoresist pattern as an etch mask.

The resist underlayer composition according to some embodiments may provide a resist underlayer that does not cause resist pattern collapse even in a fine patterning process and has improved sensitivity to an exposure light source, thereby improving patterning performance and energy efficiency.

Additionally, the resist underlayer composition according to some embodiments may provide a resist underlayer having excellent pattern formability and sensitivity.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1-6 are cross-sectional views illustrating a method of forming a pattern using a resist underlayer composition according to some embodiments.

### DETAILED DESCRIPTION

Example embodiments of the present disclosure will hereinafter be described in more detail, and may be easily performed by a person skilled in the art upon reviewing the present disclosure. However, the subject matter of this disclosure may be embodied in many different forms and is not construed as limited to the example embodiments set forth herein.

In the accompanying drawings, the thickness of layers, films, panels, regions, etc., may be exaggerated for clarity and like reference numerals designate like elements throughout the specification. It will be understood that if an element such as a layer, film, region, or substrate is referred to as being “on” another element, it may be directly on the other element or intervening elements may also be present. In contrast, if an element is referred to as being “directly on” another element, there are no intervening elements present.

As used herein, if a definition is not otherwise provided, ‘substituted’ refers to replacement of a hydrogen atom of a compound by a substituent selected from a deuterium, a halogen atom (F, Br, Cl, or I), a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C30 heterocyclic group, and a combination thereof.

In addition, two adjacent substituents of the substituted halogen atom (F, Br, Cl, or I), hydroxy group, nitro group, cyano group, amino group, azido group, amidino group, hydrazino group, hydrazono group, carbonyl group, carbamyl group, thiol group, ester group, carboxyl group or salt thereof, sulfonic acid group or salt thereof, phosphoric acid or salt thereof, C1 to C30 alkyl group, C2 to C30 alkenyl group, C2 to C30 alkynyl group, C6 to C30 aryl group, C7 to C30 arylalkyl group, C1 to C30 alkoxy group, C1 to C20 heteroalkyl group, C3 to C20 heteroarylalkyl group, C3 to C30 cycloalkyl group, C3 to C15 cycloalkenyl group, C6 to C15 cycloalkynyl group, or C2 to C30 heterocyclic group may be fused with each other to form a ring.

As used herein, if a definition is not otherwise provided, “hetero” refers to one including 1 to 3 heteroatoms selected from N, O, S, Se, and P.

As used herein, “aryl group” refers to a group having at least one hydrocarbon aromatic moiety, and broadly hydrocarbon aromatic moieties linked by a single bond (e.g., a single covalent bond) and a non-aromatic fused ring including hydrocarbon aromatic moieties fused directly or indirectly. An aryl group may be monocyclic, polycyclic, or fused polycyclic (i.e., rings sharing adjacent pairs of carbon atoms) functional group.

As used herein, “heterocyclic group” includes a heteroaryl group, and a cyclic group including at least one heteroatom selected from N, O, S, P, and Si instead of carbon © of a cyclic compound such as an aryl group, a cycloalkyl group, a fused ring thereof, or a combination thereof. If the heterocyclic group is a fused ring, each or entire ring of the heterocyclic group may include at least one heteroatom.

More specifically, a substituted or unsubstituted aryl group and/or a substituted or unsubstituted heterocyclic group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzothiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted fluorenyl group, a substituted or unsubstituted dibenzofuranyl group, a substituted or unsubstituted dibenzothiophenyl group, a substituted or unsubstituted carbazolyl group, a pyridoindolyl group, a benzopyridooxazinyl group, a benzopyridothiazinyl group, a 9,9-dimethyl-9,10-dihydroacridinyl group, a combination thereof, or a combined fused ring of the foregoing groups, but is not limited thereto.

As used herein, if specific definition is not otherwise provided, the term “combination” refers to mixing or copolymerization.

Additionally, as used herein, “polymer” may include both oligomers and polymers.

As used herein, if a definition is not otherwise provided, “weight average molecular weight” is measured by dissolving a powder sample (the column is Shodex LF-804 and the standard sample is Shodex polystyrene) in tetrahydrofuran (THF) and using Agilent Technologies' 1200 series Gel Permeation Chromatography (GPC).

As used herein, if a definition is not otherwise provided, ‘*’ refers to a linking point of the structural unit of the compound or the moiety of the compound.

In the semiconductor industry, there is a constant demand to reduce the size of chips. In order to meet this trend, a line width of the resist patterned in lithography technology should be reduced to a level of several tens of nanometers, and the pattern formed in this way is used to transfer the pattern to a lower material by using an etching process on a lower substrate. However, as the pattern size of the resist becomes smaller, a height (aspect ratio) of the resist that can withstand the line width is limited, and accordingly, the resists may not have sufficient resistance in the etching step. Therefore, a resist underlayer has been used to compensate for this if a thin resist material is used, if the substrate to be etched is thick, and/or if a deep pattern is required.

The resist underlayer is required to become thinner as the thickness of the resist becomes thinner, and the photoresist pattern should not collapse even if the resist underlayer is thin. For this purpose, the resist underlayer must have excellent adhesion to the photoresist. In addition, in forming a thin resist underlayer, the coating uniformity of the resist underlayer composition and the flatness of the resist underlayer produced therefrom should be improved, and the sensitivity to the exposure light source should be improved to improve pattern formability and energy efficiency.

A resist underlayer composition according to some embodiments includes a polymer including a structural unit represented by Chemical Formula 1, a structural unit represented by Chemical Formula 2, or a combination thereof, a compound represented by Chemical Formula 3, and a solvent:

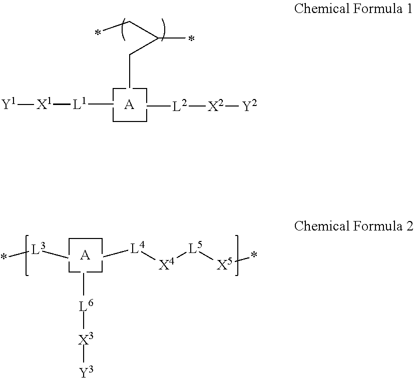

wherein, in Chemical Formula 1 and Chemical Formula 2,
A is a heterocyclic group including a nitrogen atom in the ring,
L¹ to L⁶ are each independently a single bond (e.g., a single covalent bond), a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C1 to C20 heteroarylene group, or a combination thereof,
X¹ to X⁵ are each independently a single bond (e.g., a single covalent bond), —O—, —S—, —S(═O)—, —S(═O)₂—, —C(═O)—, —(CO)O—, —O(CO)O—, —NR^{a}— (wherein R^{a} is hydrogen, deuterium, or a C1 to C10 alkyl group), or a combination thereof,
Y¹ to Y³ are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C3 to C20 heteroaryl group, or a combination thereof, and
* is a linking point:

(R¹)ₓ(R²)_{y}(R³)Sn—(R⁴)_{(3-x-y)}. Chemical Formula 3

In Chemical Formula 3,
R¹, R², and R⁴ are each independently hydrogen, deuterium, a cyano group, an oxo group (═O), an azido group —N₃, a halogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 heteroalkyl group, a substituted or unsubstituted C2 to C20 heteroalkenyl group, a substituted or unsubstituted C2 to C20 heteroalkynyl group, a substituted or unsubstituted C3 to C20 cycloalkyl group, a substituted or unsubstituted C2 to C20 heterocycloalkyl group, a substituted or unsubstituted C6 to C30 aryl group, a substituted or unsubstituted C3 to C30 heteroaryl group, —OR^{b}, —C(═O)R^{c}, —C(═O)OR^{d}, —OC(═O)OR^{e}, —NR^{f}R^{g}, —NR^{h}(C═O)Rⁱ (wherein R^{b} to Rⁱ are each independently hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, or a substituted or unsubstituted C6 to C30 aryl group), or a combination thereof,
R³ is —ORI, —C(═O)R^{k}, —C(═O)OR^{l}, or —OC(═O)OR^{m}, or -L^{a}-O—Rⁿ (wherein L^{a} is a substituted or unsubstituted C1 to C5 alkylene group, or a substituted or unsubstituted C6 to C16 arylene group, and R^{j} to Rⁿ are each independently hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, or a substituted or unsubstituted C6 to C20 aryl group),
x and y are each independently one selected from integers from 0 to 2, and 0≤x+y≤2.

In the resist underlayer composition according to some embodiments, the structural unit represented by Chemical Formula 1 and the structural unit represented by Chemical Formula 2 include a hetero ring including a nitrogen atom in a ring, so that the polymer including these structural units are capable of sp²-sp² bonding between polymers. While the present application is not limited to any particular mechanism or theory, it is believed that this allows the polymer to have high electron density and that by including a polymer have high electron density, the underlayer composition according to some embodiments may provide a film having a dense structure in the form of an ultra-thin film. In some embodiments, the high electron density of the polymer can have the effect of improving light absorption efficiency if exposing the resist underlayer composition to light. In some embodiments, by including the heterocyclic skeleton, the etch selectivity is improved, and energy efficiency can be improved if forming patterns after exposure using high-energy rays such as EUV (extreme ultraviolet; wavelength 13.5 nm) and E-Beam (electron beam).

Because the composition includes the compound represented by Chemical Formula 3, the resist underlayer formed from the composition according to some embodiments may have a structure similar to a photoresist film. Because of this, the interface between the photoresist film and the resist underlayer can be stabilized. The compound represented by Chemical Formula 3 can improve sensitivity by increasing the absorption rate of the EUV light source by including tin (Sn). As a result, the reactivity between the resist underlayer and the photoresist film may be increased, and the adhesion with the photoresist may be improved. For example, if the composition is irradiated with an EUV light source, Sn of the compound included in the composition may be combined with additives and/or polymers in the photoresist composition, and can also be combined with oxygen and/or polymers of other compounds in the resist underlayer composition according to some embodiments. Accordingly, the adhesion between the resist underlayer manufactured from the composition according to some embodiments and the photoresist may be improved.

In some embodiments, because the compound included in the composition includes tin, it may be effectively and selectively removed by a developer during development of the resist underlayer. As a result, pattern formability of the resist underlayer may be improved.

The A of Chemical Formula 1 and/or Chemical Formula 2 may be represented by one or more selected from Chemical Formula A-1 to Chemical Formula A-4:

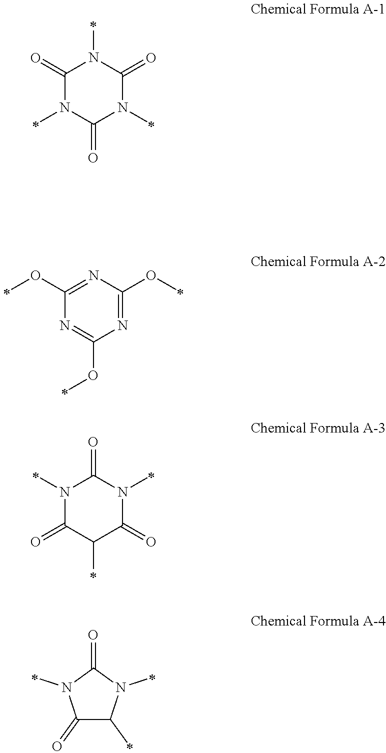

wherein, in Chemical Formula A-1 to Chemical Formula A-4, * represents a portion linked to another atom or group.

In some embodiments, L¹ to L⁶ are each independently a single bond (e.g., a single covalent bond), a substituted or unsubstituted C1 to C10 alkylene group, a substituted or unsubstituted C1 to C10 heteroalkylene group, or a combination thereof, for example, a single bond (e.g., a single covalent bond), a substituted or unsubstituted C1 to C5 alkylene group, a substituted or unsubstituted C1 to C5 heteroalkylene group, or a combination thereof, but are not limited thereto.

X¹ to X⁵ are each independently a single bond (e.g., a single covalent bond), —O—, —S—, —C(═O)—, —(CO)O—, —O(CO)O—, or a combination thereof, for example —O—, —S—, —(CO)O—, or a combination thereof, but are not limited thereto.

Y¹ to Y³ are each independently a substituted or unsubstituted C1 to C10 alkyl group, a substituted or unsubstituted C2 to C10 alkenyl group, a substituted or unsubstituted C1 to C10 heteroalkyl group, a substituted or unsubstituted C2 to C10 heteroalkenyl group, a substituted or unsubstituted C3 to C20 cycloalkyl group, a substituted or unsubstituted C2 to C20 heterocycloalkyl group, a substituted or unsubstituted C6 to C20 aryl group, or a combination thereof, for example a substituted or unsubstituted C1 to C5 alkyl group, a substituted or unsubstituted C2 to C5 alkenyl group, a substituted or unsubstituted C3 to C10 cycloalkyl group, a substituted or unsubstituted C6 to C10 aryl group, or a combination thereof, but are not limited thereto.

The structural unit represented by Chemical Formula 1 may be represented by Chemical Formula 1-1 or Chemical Formula 1-2 and the structural unit represented by Chemical Formula 2 may be represented by any one selected from Chemical Formula 2-1 to Chemical Formula 2-3:

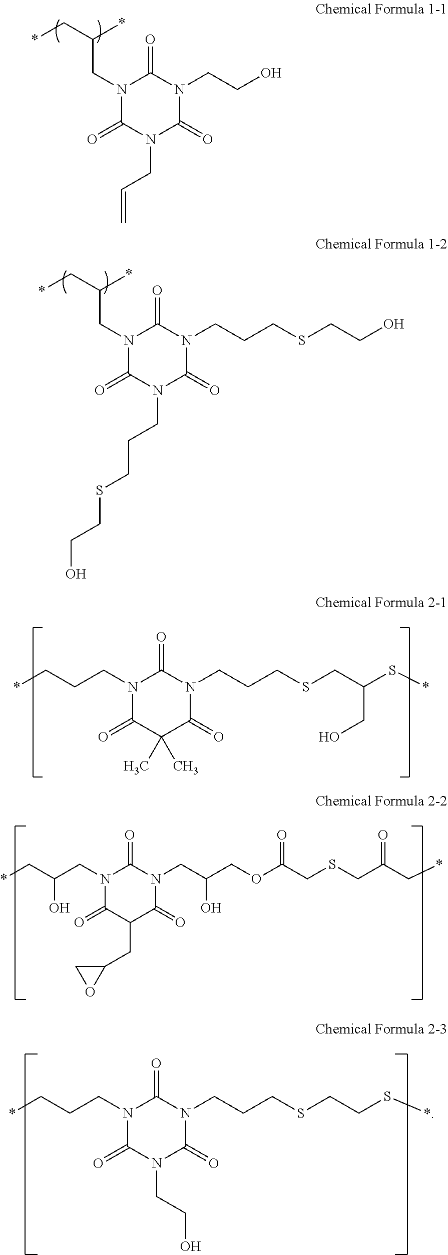

In Chemical Formula 3, at least one selected from R¹, R², and R⁴ may be a cyano group, an oxo group (═O), an azido group (—N₃), —OR^{b}, —C(═O)R^{c}, —C(═O)OR^{d}, —OC(═O)OR^{e}, —NR^{f}R^{g}, or —NR^{h}(C═O)Rⁱ (wherein R^{b} to Rⁱ are each independently hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, or a substituted or unsubstituted C6 to C30 aryl group). As described above, at least one of the remaining substituents excluding R³ has a functional group capable of reacting with another compound and/or polymer, thereby increasing reactivity with the photoresist film, and increasing adhesion between the resist underlayer according to some embodiments and the photoresist.

For example, R¹, R², and R⁴ may each independently be an oxo group (═O), an azido group (—N₃), a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C30 aryl group, —OR^{b}, NR^{f}R^{g}, —NR^{h}(C═O)Rⁱ (wherein R^{b}, and R^{f} to Rⁱ are each independently hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, or a substituted or unsubstituted C6 to C30 aryl group), or a combination thereof and R³ may be —OR^{j} (wherein R^{j} is hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, a substituted or unsubstituted C6 to C20 aryl group, or a combination thereof).

For example, R¹, R², and R⁴ may each independently be hydrogen, deuterium, an oxo group (═O), a substituted or unsubstituted C1 to C20 alkyl group, a substituted or unsubstituted C1 to C20 heteroalkyl group, a substituted or unsubstituted C6 to C30 aryl group, —OR^{b}, —C(═O)R^{c}, —C(═O)OR^{d}, —OC(═O)OR^{e} (wherein R^{b} to R^{e} are each independently hydrogen, deuterium, a substituted or unsubstituted C1 to C10 alkyl group, or a substituted or unsubstituted C6 to C30 aryl group), or a combination thereof and R³ may be —OR^{j}, or —C(═O)OR^{l}, or -L^{a}-O—Rⁿ(wherein L^{a} is a substituted or unsubstituted C1 to C5 alkylene group, R^{j}, R^{l}, and Rⁿ are each independently hydrogen, deuterium, a substituted or unsubstituted C1 to C10 alkyl group, a substituted or unsubstituted C1 to C10 heteroalkyl group, a substituted or unsubstituted C6 to C20 aryl group, or a combination thereof).

In some embodiments, if R¹, R², and R⁴ are selected from —OR^{b}, or —OC(═O)OR^{e}, R^{b} and R^{e} may each independently be hydrogen, deuterium, substituted or unsubstituted C1 to C8 alkyl group, a substituted or unsubstituted C2 to C8 alkenyl group, a substituted or unsubstituted C2 to C8 alkynyl group, a substituted or unsubstituted C3 to C8 cycloalkyl group, a substituted or unsubstituted C6 to C20 aryl group, or a combination thereof, and for example, hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

In some embodiments, the compound represented by Chemical Formula 3 may be represented by any one or more selected from Chemical Formula 3-1 to Chemical Formula 3-4:

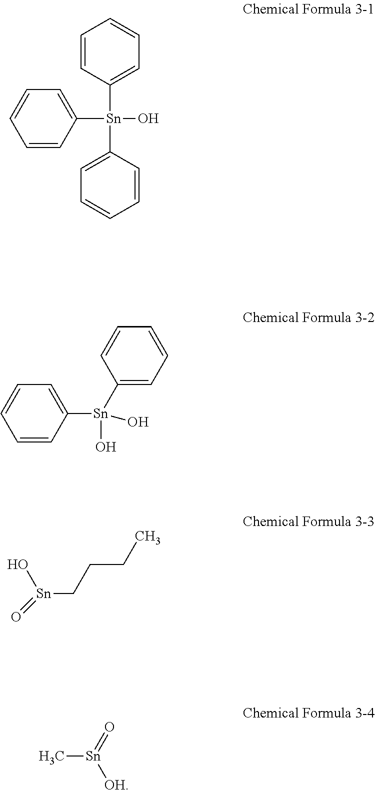

The polymer may have a weight average molecular weight of about 1,000 g/mol to about 300,000 g/mol, for example about 3,000 g/mol to about 200,000 g/mol, for example about 3,000 g/mol to about 100,000 g/mol, for example about 3,000 g/mol to about 90,000 g/mol, for example about 3,000 g/mol to about 70,000 g/mol, for example about 3,000 g/mol to about 70,000 g/mol, for example about 3,000 g/mol to about 50,000 g/mol, for example about 5,000 g/mol to about 50,000 g/mol, or, for example, about 5,000 g/mol to about 30,000 g/mol, but is not limited thereto. By having a weight average molecular weight within the above ranges, a carbon content and solubility in the solvent of the resist underlayer composition including the polymer may be adjusted and/or optimized or improved.

The compound may be included in an amount of about 10 parts by weight to about 800 parts by weight, for example about 20 parts by weight to about 800 parts by weight, for example about 30 parts by weight to about 800 parts by weight, for example about 30 parts by weight to about 700 parts by weight, for example about 30 parts by weight to about 600 parts by weight, or, for example about 30 parts by weight to about 500 parts by weight based on 100 parts by weight of polymer, but is not limited thereto. By including the compound in the above ranges based on the polymer content, an adhesion between the resist and the film formed from the resist underlayer composition including the same may be optimized or improved, and the sensitivity to the exposure light source may be improved, thereby improving patterning performance and energy efficiency.

The polymer may be included in an amount of about 0.1 wt % to about 50 wt % based on a total weight of the resist underlayer composition. In some embodiments, the polymer may be included in an amount of about 10 wt % to about 50 wt %, for example about 20 wt % to about 50 wt %, or, for example about 20 wt % to about 30 wt %, based on a total weight of the resist underlayer composition, but is not limited thereto. By including the polymer within the above ranges in the composition, the thickness, surface roughness, and a degree of planarization of the resist underlayer may be adjusted.

The compound may be included in an amount of about 0.01 wt % to about 30 wt % based on a total weight of the resist underlayer composition. In some embodiments, the compound may be included in an amount of about 0.1 wt % to about 30.0 wt %, for example about 1.0 wt % to about 30.0 wt %, for example about 5.0 wt % to about 30.0 wt %, for example about 5.0 wt % to about 25.0 wt %, for example about 8.0 wt % to 2 about 5.0 wt %, or, for example about 10.0 wt % to about 25.0 wt % based on a total weight of the resist underlayer composition, but is not limited thereto. By including the compound in the above ranges, the thickness, surface roughness, chemical resistance, and degree of planarization of the resist underlayer may be adjusted.

The resist underlayer composition according to some embodiments may include a solvent. The solvent is not particularly limited as long as it has suitable or sufficient solubility and/or dispersibility for the polymer and compound according to some embodiments, but may be, for example, propylene glycol, propylene glycol diacetate, methoxypropanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, methyl 2-hydroxyisobutyrate, acetylacetone, ethyl 3-ethoxypropionate, or a combination thereof.

The resist underlayer composition according to some embodiments may further include one or more polymers selected from an acrylic resin, an epoxy resin, a novolac-based resin, a glycoluril-based resin, and a melamine-based resin, in addition to the polymer, compound, and solvent, but is not limited thereto.

The resist underlayer composition according to some embodiments may further include an additive including a surfactant, a thermal acid generator, a plasticizer, or a combination thereof.

The surfactant may be used to improve coating defects that occur as the solid content increases if forming a resist underlayer. For example, the surfactant may be an alkylbenzenesulfonic acid salt, an alkylpyridinium salt, polyethylene glycol, a quaternary ammonium salt, etc., but is not limited thereto.

The thermal acid generator may be, for example, an acidic compound such as p-toluenesulfonic acid, trifluoromethanesulfonic acid, pyridinium p-toluenesulfonate, salicylic acid, sulfosalicylic acid, citric acid, benzoic acid, hydroxybenzoic acid, naphthalenecarboxylic acid, and/or benzoin tosylate, 2-nitrobenzyltosylate, and/or other organic sulfonic acid alkyl esters, but is not limited thereto.

The plasticizer is not particularly limited, and various suitable types (or kinds) of plasticizers generally used in the art may be used. Examples of the plasticizer may include low molecular weight compounds such as phthalic acid esters, adipic acid esters, phosphoric acid esters, trimellitic acid esters, and citric acid esters, and polyether-based, polyester-based, and polyacetal-based compounds.

The additive may be included in an amount of about 0.001 to about 40 parts by weight based on 100 parts by weight of the resist underlayer composition. By including it within the above ranges, solubility may be improved without (or substantially without) changing the optical properties of the resist underlayer composition.

According to some embodiments, a resist underlayer manufactured using the aforementioned resist underlayer composition is provided. The resist underlayer may be, for example, obtained by coating the aforementioned resist underlayer composition on a substrate and then curing through a heat treatment process.

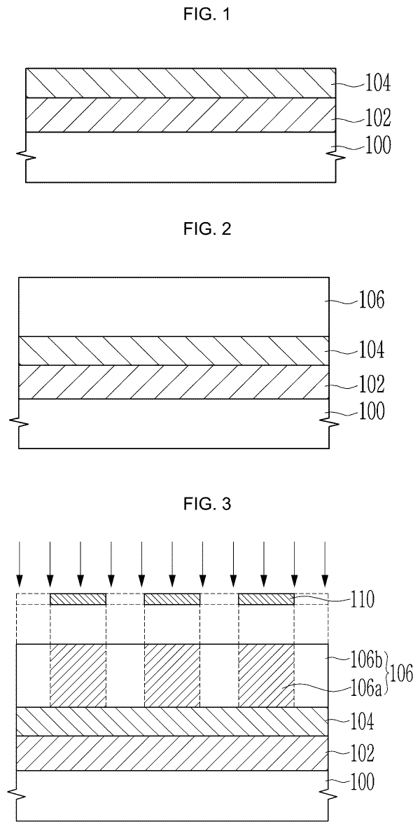

Hereinafter, a method of forming a pattern using the aforementioned resist underlayer composition will be described with reference to FIGS. 1-6. FIGS. 1-6 are cross-sectional views illustrating a method of forming a pattern using the resist underlayer composition according to embodiments of the present disclosure.

Referring to FIG. 1, first, an object to be etched is prepared. An example of the object to be etched may be a thin film 102 on a semiconductor substrate 100. Hereinafter, only embodiments where the object to be etched is the thin film 102 will be described, but the present disclosure is not limited thereto. The surface of the thin film 102 is cleaned to remove contaminants remaining on the thin film 102. The thin film 102 may be, for example, a silicon nitride film, a polysilicon film, and/or a silicon oxide film.

Subsequently, the aforementioned resist underlayer composition is coated on the surface of the cleaned thin film 102 using a spin coating method.

Then, drying and baking processes are performed to form a resist underlayer 104 on the thin film. The baking treatment may be performed at about 100° C. to about 500° C., for example, at about 100° C. to about 300° C. A more detailed description of the resist underlayer composition is not repeated here to avoid duplication because it has been described in more detail above.

Referring to FIG. 2, a photoresist is coated on the resist underlayer 104 to form a photoresist film 106. In some embodiments, the photoresist composition that forms the photoresist film 106 may include an organometallic compound including Sn, a solvent, etc., but is not limited thereto.

Subsequently, a first baking process is performed to heat the substrate 100 on which the photoresist film 106 is formed. The first baking process may be performed at a temperature of about 90° C. to about 120° C.

For example, the photoresist film 106 of FIG. 2 may have a tin oxide network formed as expressed in Formula 1.

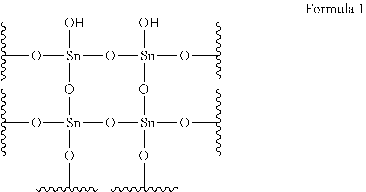 [SMILES: *[O][Sn]1([OH])[O][Sn]([OH])([O]*)[O][Sn]([O]*)([O]*)[O][Sn]([O]*)([O]*)[O]1]

In some embodiments, as shown in Formula 2, the resist underlayer 104 may form a dense network by combining the compound represented by Chemical Formula 3 included in the resist underlayer composition according to some embodiments with the polymer including the structural unit represented by Chemical Formula 1 and/or Chemical Formula 2. In Formula 2, M¹ to M¹⁰ are structural units represented by Chemical Formula 1 and/or Chemical Formula 2, and R_{S} are substituents corresponding to R¹ to R⁴ in Chemical Formula 3. As shown in Formula 2, the compound represented by Chemical Formula 3 in the resist underlayer formed from the composition according to some embodiments is randomly combined with each structural unit of the polymer including the structural units represented by Chemical Formula 1 and/or Chemical Formula 2.

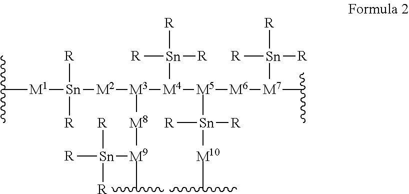

As shown in Formula 2, at the interface between the resist underlayer 104 and the photoresist film 106 according to some embodiments, through the tin oxide bond between tin and oxygen, the compound included in the resist underlayer 104 and/or the structural unit of the polymer bound thereto can bind to tin forming the photoresist film 106. This is schematically illustrated in Formula 3, and in Formula 3, the central dotted line represents the boundary between the resist underlayer 104 and the photoresist film 106.

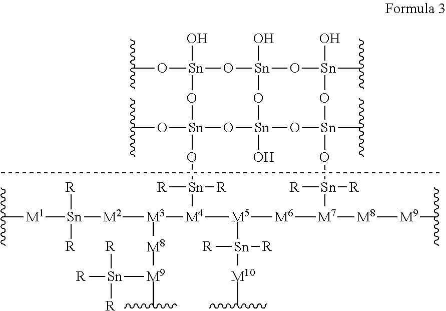

Formulas 1 to 3 are shown as examples to illustrate embodiments of the present disclosure, and do not mean that the structure forming the resist underlayer or photoresist film is limited to these.

Referring to FIG. 3, the photoresist film 106 is selectively exposed. To explain the exposure process for exposing the photoresist film 106 as an example, an exposure mask having a set or predetermined pattern is placed on the mask stage of an exposure apparatus, and an exposure mask 110 is placed on the photoresist film 106. Subsequently, by irradiating light to the mask 110, a set or predetermined portion of the photoresist film 106 formed on the substrate 100 selectively reacts with the light passing through the exposure mask.

For example, examples of light that can be used in the exposure process may include short-wavelength light such as i-line activating radiation having a wavelength of 365 nm, a KrF excimer laser having a wavelength of 248 nm, and an ArF excimer laser having a wavelength of 193 nm. In some embodiments, EUV (Extreme ultraviolet), which has a wavelength of 13.5 nm, which corresponds to extreme ultraviolet light, may be used.

An exposed region 106b of the photoresist film 106 has a different solubility from an unexposed region 106a of the photoresist film 106 as a polymer is formed through a crosslinking reaction such as a condensation reaction between organometallic compounds.

Subsequently, a second baking process is performed on the substrate 100. The second baking process may be performed at a temperature of about 90° C. to about 200° C. By performing the second baking process, the exposed region 106b of the photoresist film 106 becomes difficult to dissolve in the developer.

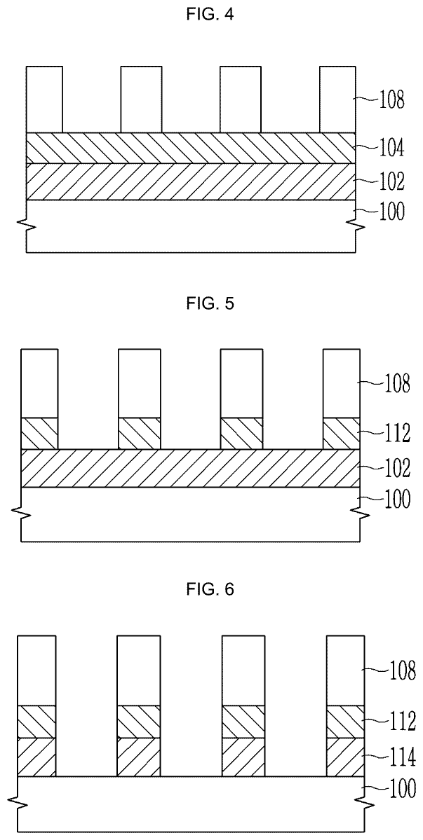

Referring to FIG. 4, the photoresist film 106a corresponding to the unexposed region is dissolved and removed using an organic solvent developer such as 2-heptanone, and thereby the photoresist film 106b remaining after development forms a photoresist pattern 108.

As described above, the developer used in the method of forming a pattern according to some embodiments may be an organic solvent. Examples of organic solvents used in the method of forming a pattern according to some embodiments may include ketones such as methyl ethyl ketone, acetone, cyclohexanone, and 2-heptanone, alcohols such as 4-methyl-2-propanol, 1-butanol, isopropanol, and 1-propanol, methanol, esters such as propylene glycol monomethyl ether acetate, ethyl acetate, ethyl lactate, n-butyl acetate, and butyrolactone, aromatic compounds such as benzene, xylene, and toluene, or a combination thereof.

However, the photoresist pattern according to some embodiments is not necessarily limited to being formed as a negative tone image, and may be formed to have a positive tone image. In some embodiments, the developer that can be used to form a positive tone image may be a quaternary ammonium hydroxide composition such as tetraethylammonium hydroxide, tetrapropylammonium hydroxide, tetrabutylammonium hydroxide, or a combination thereof.

As explained above, the photoresist pattern 108 formed by exposure to high-energy light such as not only light having wavelengths such as i-line (wavelength: 365 nm), KrF excimer laser (wavelength: 248 nm), and/or ArF excimer laser (wavelength: 193 nm), but also EUV (Extreme UltraViolet; wavelength: 13.5 nm) and/or an E-Beam may have a width of about 5 nm to about 100 nm thick. For example, the photoresist pattern 108 may be formed to have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

In some embodiments, the photoresist pattern 108 may have a pitch having a half-pitch of less than or equal to about 50 nm, for example less than or equal to about 40 nm, for example less than or equal to about 30 nm, for example less than or equal to about 20 nm, or for example less than or equal to about 10 nm and a line width roughness of less than or equal to about 5 nm, less than or equal to about 3 nm, less than or equal to about 2 nm, or less than or equal to about 1 nm.

Subsequently, the resist underlayer 104 is etched using the photoresist pattern 108 as an etch mask. An organic film pattern 112 as shown in FIG. 5 is formed through the above etching process.

The formed organic film pattern 112 may also have a width corresponding to the photoresist pattern 108. The etching may be performed, for example, by dry etching using an etching gas, and the etching gas may be, for example, CHF₃, CF₄, Cl₂, Od, or a mixture thereof. As described above, because the resist underlayer formed by the resist underlayer composition according to some embodiments has a fast etch rate, a smooth etching process can be performed within a short time.

Referring to FIG. 6, the exposed thin film 102 is etched by applying the photoresist pattern 108 as an etch mask. As a result, the thin film is formed into a thin film pattern 114.

In the exposure process performed as described above, the thin film pattern formed by the exposure process performed using short-wavelength light sources such as the activating radiation i-line (wavelength: 365 nm), KrF excimer laser (wavelength: 248 nm), and/or ArF excimer laser (wavelength: 193 nm) 114) may have a width of tens to hundreds of nanometers and the thin film pattern 114 formed by an exposure process performed using an EUV light source may have a width of less than or equal to about 20 nm.

Hereinafter, embodiments of the present disclosure will be described in more detail through examples related to the synthesis of the aforementioned polymer and the preparation of a resist underlayer composition including the same. However, the present disclosure is not technically limited by the following examples.

### Synthesis of Polymers

### Synthesis Example 1

24.9 g of 1,3-diallyl-5-(2-hydroxyethyl) isocyanurate, 7.4 g of mercapto ethanol, 0.7 g of azobisisobutyronitrile (AIBN), and 48 g of N,N-dimethyl formamide (DMF) are added to a 500 ml 3-necked round flask, and a condenser is connected thereto. After a reaction proceeds at 80° C. for 16 hours, the resultant reaction solution is cooled to room temperature. The reaction solution is added dropwise to a 1 L wide-mouth bottle including 800 g of water, while stirring, to produce a gum, which is dissolved in 80 g of tetrahydrofuran (THF). The dissolved resin solution is treated with toluene to form precipitates, while removing single molecules and low molecular weight molecules. Finally, 10 g of Polymer A represented by Chemical Formula 1-1 is obtained. (a weight average molecular weight (Mw)=10,500 g/mol)

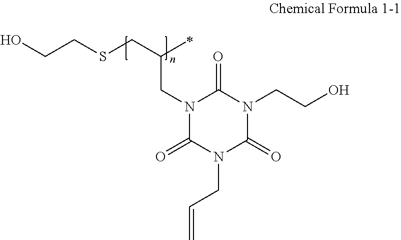

### Synthesis Example 2

24.9 g of 1,3,5-triallyl-1,3,5-triazinane-2,4,6-trione), 7.4 g of mercapto ethanol, 0.7 g of AIBN (azobisisobutyronitrile), and 48 g of N,N-dimethyl formamide (DMF) are put in a 500 ml 3-necked round flask, and a condenser is connected thereto. After a reaction proceeds at 80° C. for 16 hours, the resultant reaction solution is cooled to room temperature. The reaction solution is added dropwise to a 1 L wide-mouth bottle including 800 g of water, while stirring, to produce a gum, which is dissolved in 80 g of tetrahydrofuran (THF). The dissolved resin solution is treated by using toluene to form precipitates, while removing single molecules and low molecular weight molecules. Finally, 10 g of Polymer B represented by Chemical Formula 1-2 is obtained. (A weight average molecular weight (Mw)=8,000 g/mol)

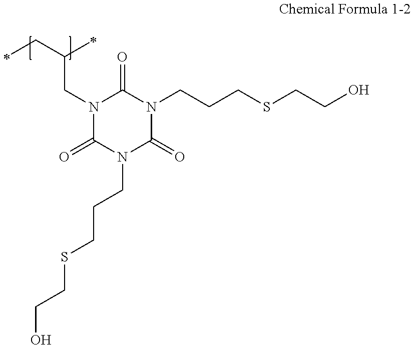

### Synthesis Example 3

20 g of 1,3-diallyl-5,5-dimethyl-1,3-diazinane-2,4,6(1H,3H,5H)-trione, 8.4 g of 2,3-dimercapto-1-propanol, 0.5 g of azobisisobutyronitrile (AIBN), and 50 g of N,N-dimethyl formamide are added to a 250 mL four-necked flask to prepare a reaction solution, and a condenser is connected thereto. The resultant reaction solution is reacted by heating at 60° C. for 5 hours and then, cooled to room temperature. Subsequently, the reaction solution is added dropwise to a beaker including 300 g of distilled water, while stirring, to produce gum, which is dissolved in 30 g of tetrahydrofuran (THF). The dissolved resin solution is treated with toluene to form precipitates, while removing single molecules and low molecular weight molecules, to finally obtain Polymer C including a structural unit represented by Chemical Formula 2-1. (A weight average molecular weight (Mw)=3,700 g/mol)

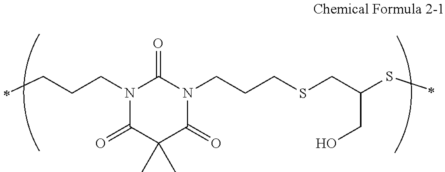

### Synthesis Example 4

148.6 g (0.5 mol) of 1,3,5-triglycidyl isocyanurate, 60.0 g (0.4 mol) of 2,2′-thiodiacetic acid, 9.1 g of benzyl triethyl ammonium chloride, and 350 g of N,N-dimethylformamide are added to a 1 L 2 necked round flask, and a condenser is connected thereto. After increasing a temperature to 100° C. and performing a reaction for 8 hours, the resultant reaction solution is cooed to room temperature (23° C.). Subsequently, the reaction solution is moved to a 1 L wide-mouth bottle and then, three times washed with hexane and subsequently, with purified water. A resin obtained in a gum state is completely dissolved in 80 g of THE and then, slowly added dropwise to 700 g of toluene, while stirring. After removing the solvent, Polymer D including a structural unit represented by Chemical Formula 2-2 is finally obtained. (A weight average molecular weight (Mw)=9,100 g/mol)

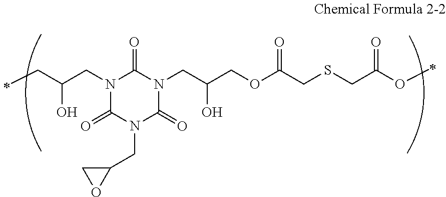

### Synthesis Example 5

20 g of 1,3-diallyl-5-(2,2-dimethyl)-isocyanurate, 6.0 g of 1,2-dithiol (ethane-1,2-dithiol), 1 g of azobisisobutyronitrile (AIBN), and 50 g of N,N-dimethyl formamide are added to a 250 mL four-necked flask to prepare a reaction solution, and a condenser is connected thereto. The resultant reaction solution is reacted by heating at 50° C. for 5 hours, and 10 g of 3,4-difluorobenzyl mercaptan and after adding 1 g of azobisisobutyronitrile (AIBN), additionally reacted for 2 hours and then, cooled to room temperature. Subsequently, the reaction solution is added dropwise to a beaker including 300 g of distilled water, while stirring, to produce a gum, which is dissolved in 30 g of tetrahydrofuran (THF). The dissolved resin solution is treated with toluene to form precipitates, while removing single molecules and low molecular weight molecules, to finally obtain Polymer E represented by Chemical Formula 2-3. (A weight average molecular weight (Mw)=5,500 g/mol)

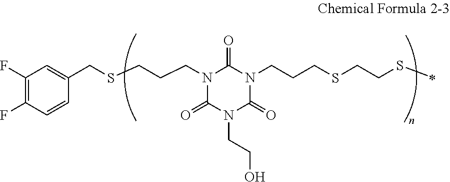

### Synthesis of Compounds

### Synthesis Example 6

11.56 g of triphenyltin chloride, 10.21 g of sodium ethoxide, and 21.77 g of methanol are added to a 100 ml 2 necked round flask, and a condenser is connected thereto. Subsequently, a reaction proceeds at 40° C. for 12 hours. After cooling the resultant reaction solution to room temperature and drying it to obtain powder, the powder is dissolved in dichloromethane and then, washed with distilled water, and an organic solution portion is taken therefrom and dried to obtain a compound represented by Chemical Formula 3-1.

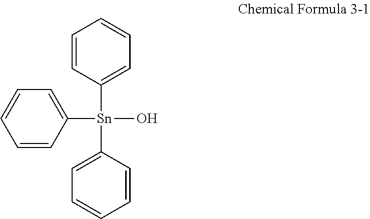 [SMILES: [OH][Sn]([c]1ccccc1)([c]1ccccc1)[c]1ccccc1]

### Synthesis Example 7

10.3 g of diphenyltin dichloride, 6.0 g of sodium hydroxide, and 16.3 g of methanol are added to a 100 ml 2 necked round flask, and a condenser is connected thereto. Subsequently, a reaction proceeds at 70° C. for 12 hours. After cooling the resultant reaction solution to room temperature and drying it to obtain powder, this powder is dissolved in dichloromethane and then, washed with distilled water, and an organic solution portion is taken therefrom and dried to obtain a compound represented by Chemical Formula 3-2.

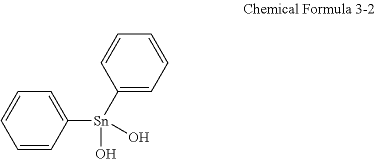 [SMILES: [OH][Sn]([OH])([c]1ccccc1)[c]1ccccc1]

### Synthesis Example 8

8.47 g of butyltin trichloride, 6.0 g of sodium hydroxide, and 14.47 g of water added to a 100 ml 2 necked round flask, and a condenser is connected thereto. Subsequently, a reaction proceeds at 55° C. for 6 hours and after increasing the temperature to 95° C., at 95° C. for 12 hours. Then, the resultant reaction solution is cooled to room temperature and dried to obtain powder, the powder is dissolved in dichloromethane and then, washed with distilled water, and an organic solution portion is taken therefrom and dried to obtain a compound represented by Chemical Formula 3-3.

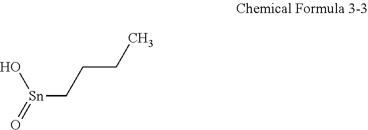

### Preparation of Resist Underlayer Compositions

### Example 1

Polymer A according to Polymerization Example 1 and the compound of Chemical Formula 3-1 according to Synthesis Example 6 are mixed together in a ratio of 100:50, and 1.2 g of the mixture, 0.4 g of PD1174 (a crosslinking agent), and 0.02 g of pyridinium para-toluenesulfonate (PPTS) are completely dissolved in propylene glycol monomethylether to a 3% solid content and then, diluted by additionally adding the solvent thereto to prepare a resist underlayer composition according to Example 1.

### Example 2

A resist underlayer composition is prepared in the same manner as in Example 1, except that the compound of Chemical Formula 3-2 according to Synthesis Example 7 is used instead of the compound according to Chemical Formula 3-1.

### Example 3

A resist underlayer composition is prepared in the same manner as in Example 1, except that the compound of Chemical Formula 3-3 according to Synthesis Example 8 is used instead of the compound according to Chemical Formula 3-1.

### Example 4

A resist underlayer composition is prepared in the same manner as in Example 1, except that the compound of Chemical Formula 3-4 (PR-79356, Atomaxchem) is used instead of the compound according to Chemical Formula 3-1.

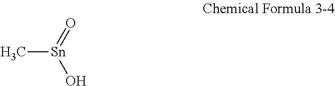

### Example 5

A resist underlayer composition is prepared in the same manner as in Example 1, except that Polymer B is used instead of Polymer A.

### Comparative Example 1

A resist underlayer composition according to Comparative Example 1 is prepared by mixing together 1.2 g of Polymer A according to Polymerization Example 1, 0.4 g of PD1174 (a cross-linking agent), and 0.02 g of pyridinium para-toluenesulfonate (PPTS), completely dissolving them in propylene glycol monomethylether to a 3% solid content, and additionally adding the solvent thereto to dilute the solution.

### Comparative Example 2

A resist underlayer composition is prepared in the same manner as in Comparative Example 1, except that Polymer B is used instead of Polymer A.

### Evaluation 1: Evaluation of Exposure Characteristics

Each of the compositions according to Examples 1 to 5 and Comparative Examples 1 and 2 is coated in a spin-on coating method and heat-treated at 205° C. on a hot plate for 60 seconds to form a 50 Å-thick resist underlayer. On the underlayer, a photoresist solution is coated in the spin-on coating method and then, heat-treated at 110° C. on the hot plate for 1 minute to form a photoresist layer. The photoresist layer is exposed within a range of 200 μC/cm² to 2000 μC/cm² by using an e-beam light exposer (Elionix Inc.) and heat-treated at 150° C. for 60 seconds. Subsequently, the photoresist layer is developed in a 2.38 mass % TMAH aqueous solution and rinsed with pure water for 15 seconds to form a photoresist pattern having a 50 nm line and space (US). Then, the photoresist pattern is evaluated with respect to an optimal exposure dose, and the results are shown in Table 1. Herein, the optimal exposure dose (optimum energy) (Eop,μC/cm²) indicates an exposure dose of developing the 50 nm line and space pattern at 1:1. In addition, minimum CD indicates a minimum size capable of well forming the pattern without line connection or collapsing, wherein the higher, the better resolution.

TABLE 1

| | Exposure | Minimum | |
|---|---|---|---|
| | dose | CD | LWR |
| | (Eop, %) | (nm) | (nm) |
| Example 1 | 85 | 49 | 4.98 96 |
| Example 2 | 88 | 47 | 4.83 93 |
| Example 3 | 82 | 48 | 4.77 92 |
| Example 4 | 89 | 46 | 4.88 94 |
| Example 5 | 91 | 44 | 4.98 96 |
| Comparative | 100 | 54 | 5.19 |
| Example 1 | | | |
| Comparative | 105 | 55 | 5.61 |
| Example 2 | | | |

Referring to Table 1, the resist underlayers of Examples 1 to 5 exhibit excellent formability and sensitivity of fine pattern (50 nm US), compared with those of Comparative Examples 1 and 2.

### Evaluation 2: Evaluation of Line Width Roughness (LWR)

Each of the compositions of Examples 1 to 5 and Comparative Examples 1 and 2 is coated in a spin-on coating method and heat-treated at 205° C. on a hot plate for 60 seconds to form a 50 Å-thick resist underlayer. Subsequently, on the underlayer, the photoresist solution is coated in a spin-on coating method and heat-treated at 110° C. on a hot plate for 1 minute to form a photoresist layer. The resist layer is exposed to have a line width of 30 nm and a space of 30 nm between lines by using an e-beam light exposer (an acceleration voltage: 100 keV, Elionix Inc.). Subsequently, the exposed resist layer is heat-treated at 95° C. for 60 seconds and developed in a 2.38 wt % tetramethylammonium hydroxide (TMAH) aqueous solution for 60 seconds and rinsed with pure water for 60 seconds to form a resist pattern.

Line width roughness (LWR) is obtained by examining a pattern having a width of 30 nm by using a scanning electron microscope (SEM)S-9260 (Hitachi, Ltd.) and measuring a distance from a reference line where an edge should be within an edge range of 2 μm in a length direction of the pattern. The results are shown in Table 1, wherein the smaller line width roughness (LWR), the better.

Referring to Table 1, the resist underlayers of Examples 1 to 5 have smaller LWR than those of Comparative Examples 1 and 2 and exhibit more uniform patterns.

Hereinbefore, example embodiments of the present disclosure have been described and illustrated, however, it should be apparent to a person having ordinary skill in the art that the present disclosure is not limited to the embodiments described herein, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure and equivalents thereof.

Description of Symbols

| | |
|---|---|
| 100: substrate | 102: thin film |
| 104: resist underlayer | 106: photoresist film |
| 106a: unexposed region | 106b: exposed region |
| 108: photoresist pattern | 110: mask |
| 112: organic film pattern | 114: thin film pattern |

What is claimed is:

1. A resist underlayer composition, comprising:
a polymer comprising a structural unit represented by Chemical Formula 1, a structural unit represented by Chemical Formula 2, or a combination thereof, a compound represented by Chemical Formula 3, and a solvent: 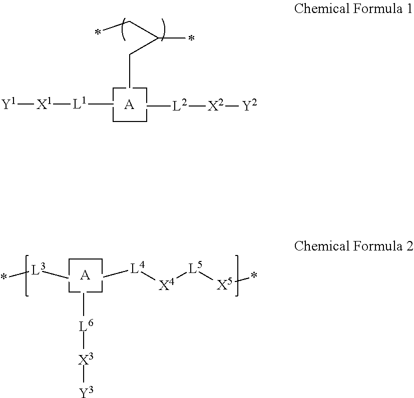
wherein, in Chemical Formula 1 and Chemical Formula 2,
A is a heterocyclic group including a nitrogen atom in a ring,
L¹ to L⁶ are each independently a single bond, a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C1 to C20 heteroarylene group, or a combination thereof,
X¹ to X⁵ are each independently a single bond, —O—, —S—, —S(═O)—, —S(═O)₂—, —C(═O)—, —(CO)O—, —O(CO)O—, —NR^{a}— (wherein R^{a} is hydrogen, deuterium, or a C1 to C10 alkyl group), or a combination thereof,
Y¹ to Y³ are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C3 to C20 heteroaryl group, or a combination thereof, and
* is a linking point:
(R¹)ₓ(R²)_{y}(R³)Sn—(R⁴)_{(3-x-y)} Chemical Formula 3
wherein, in Chemical Formula 3,
R¹, R², and R⁴ are each independently hydrogen, deuterium, a cyano group, an oxo group (═O), an azido group (—N₃), a halogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 heteroalkyl group, a substituted or unsubstituted C2 to C20 heteroalkenyl group, a substituted or unsubstituted C2 to C20 heteroalkynyl group, a substituted or unsubstituted C3 to C20 cycloalkyl group, a substituted or unsubstituted C2 to C20 heterocycloalkyl group, a substituted or unsubstituted C6 to C30 aryl group, a substituted or unsubstituted C3 to C30 heteroaryl group, —OR^{b}, —C(═O)R^{c}, —C(═O)OR^{d}, —OC(═O)OR^{e}, —NR^{f}R^{g}, —NR^{h}(C═O)Rⁱ (wherein R^{b} to Rⁱ are each independently hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, or a substituted or unsubstituted C6 to C30 aryl group), or a combination thereof,
R³ is —OR^{j}, —C(═O)R^{k}, —C(═O)OR^{l}, —OC(═O)OR^{m}, or -L^{a}-O—Rⁿ (wherein L^{a} is a substituted or unsubstituted C1 to C5 alkylene group, or a substituted or unsubstituted C6 to C16 arylene group, and R^{j} to Rⁿ are each independently hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, or a substituted or unsubstituted C6 to C20 aryl group),
x and y are each independently one selected from integers from 0 to 2, and 0≤x+y≤2.

2. The resist underlayer composition as claimed in claim 1, wherein the A of Chemical Formula 1 and Chemical Formula 2 is represented by one or more selected from Chemical Formula A-1 to Chemical Formula A-4: 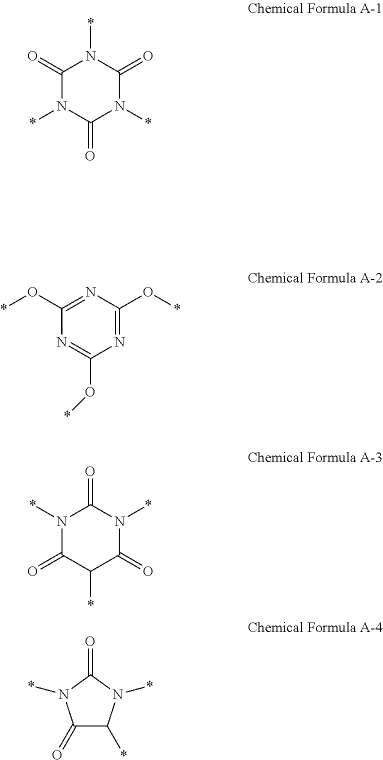
wherein, in Chemical Formula A-1 to Chemical Formula A-4, * represents a portion linked to another atom or group.

3. The resist underlayer composition as claimed in claim 1, wherein L¹ to L⁶ are each independently a single bond, a substituted or unsubstituted C1 to C10 alkylene group, a substituted or unsubstituted C1 to C10 heteroalkylene group, or a combination thereof,
X¹ to X⁵ are each independently a single bond, —O—, —S—, —C(═O)—, —(CO)O—, —O(CO)O—, or a combination thereof, and
Y¹ to Y³ are each independently a substituted or unsubstituted C1 to C10 alkyl group, a substituted or unsubstituted C2 to C10 alkenyl group, a substituted or unsubstituted C1 to C10 heteroalkyl group, a substituted or unsubstituted C2 to C10 heteroalkenyl group, a substituted or unsubstituted C3 to C20 cycloalkyl group, a substituted or unsubstituted C2 to C20 heterocycloalkyl group, a substituted or unsubstituted C6 to C20 aryl group, or a combination thereof.

4. The resist underlayer composition as claimed in claim 1, wherein at least one selected from R¹, R², and R⁴ is a cyano group, an oxo group (═O), an azido group (—N₃), —OR^{b}, —C(═O)R^{c}, —C(═O)OR^{d}, —OC(═O)OR^{e}, —NR^{f}R^{g}, or —NR^{h}(C═O)Rⁱ (wherein R^{b} to Rⁱ are each independently hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, or a substituted or unsubstituted C6 to C30 aryl group).

5. The resist underlayer composition as claimed in claim 1, wherein R¹, R², and R⁴ are each independently an oxo group (═O), an azido group (—N₃), a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C30 aryl group, —OR^{b}, NR^{f}R^{g}, —NR^{h}(C═O)Rⁱ (wherein R^{b}, and R^{f} to Rⁱ are each independently hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, or a substituted or unsubstituted C6 to C30 aryl group), or a combination thereof, and
R³ is —OR^{j} (wherein R^{j} is hydrogen, deuterium, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C1 to C10 heteroalkyl group, a substituted or unsubstituted C6 to C20 aryl group, or a combination thereof).

6. The resist underlayer composition as claimed in claim 1, wherein R¹, R², and R⁴ are each independently hydrogen, deuterium, an oxo group (═O), a substituted or unsubstituted C1 to C20 alkyl group, a substituted or unsubstituted C1 to C20 heteroalkyl group, a substituted or unsubstituted C6 to C30 aryl group, —OR^{b}, —C(═O)R^{c}, —C(═O)OR^{d}, —OC(═O)OR^{e} (wherein R^{b} to R^{e} are each independently hydrogen, deuterium, a substituted or unsubstituted C1 to C10 alkyl group, or a substituted or unsubstituted C6 to C30 aryl group), or a combination thereof, and
R³ is —OR^{j}, —C(═O)OR^{l}, or -L^{a}-O—Rⁿ (wherein L^{a} is a substituted or unsubstituted C1 to C5 alkylene group, R^{j}, R^{l}, and Rⁿ are each independently hydrogen, deuterium, a substituted or unsubstituted C1 to C10 alkyl group, a substituted or unsubstituted C1 to C10 heteroalkyl group, a substituted or unsubstituted C6 to C20 aryl group, or a combination thereof).

7. The resist underlayer composition as claimed in claim 1, wherein the structural unit represented by Chemical Formula 1 is represented by Chemical Formula 1-1 or Chemical Formula 1-2, and the structural unit represented by Chemical Formula 2 is represented by any one selected from Chemical Formula 2-1 to Chemical Formula 2-3:

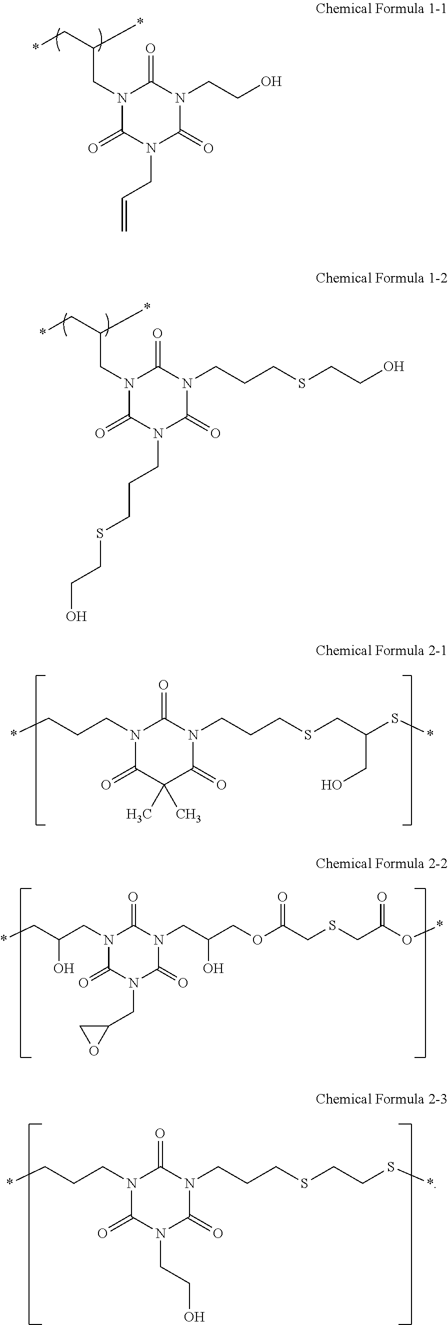

8. The resist underlayer composition as claimed in claim 1, wherein the compound represented by Chemical Formula 3 is represented by any one or more selected from Chemical Formula 3-1 to Chemical Formula 3-4:

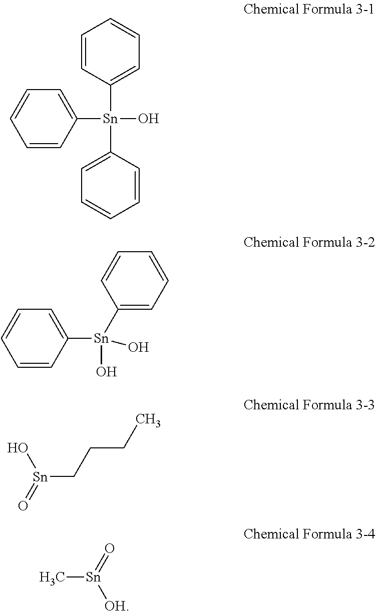

9. The resist underlayer composition as claimed in claim 1, wherein a weight average molecular weight of the polymer is about 1,000 g/mol to about 300,000 g/mol.

10. The resist underlayer composition as claimed in claim 1, wherein the compound is included in an amount of about 10 to about 800 parts by weight based on 100 parts by weight of the polymer.

11. The resist underlayer composition as claimed in claim 1, wherein the compound is included in an amount of about 30 parts by weight to about 500 parts by weight based on 100 parts by weight of the polymer.

12. The resist underlayer composition as claimed in claim 1, wherein the polymer is included in an amount of about 0.1 wt % to about 50 wt % based on a total weight of the resist underlayer composition.

13. The resist underlayer composition as claimed in claim 1, wherein the compound is included in an amount of about 0.01 wt % to about 30 wt % based on a total weight of the resist underlayer composition.

14. The resist underlayer composition as claimed in claim 1, wherein the resist underlayer composition further comprises one or more additional polymers selected from an acrylic resin, an epoxy resin, a novolac-based resin, a glycoluril-based resin, and a melamine-based resin.

15. The resist underlayer composition as claimed in claim 1, wherein the resist underlayer composition further comprises additives comprising a surfactant, a thermal acid generator, a photo acid generator, a plasticizer, or a combination thereof.

16. A method of forming a pattern, comprising:
forming a film to be etched on a substrate,
coating the resist underlayer composition as claimed in claim 1 on the film to be etched to form a resist underlayer,
forming a photoresist pattern on the resist underlayer, and
etching the resist underlayer and the film to be etched sequentially using the photoresist pattern as an etch mask.
